(19) United States
(12) Patent Application Publication
(10) Pub. No.: US 2024/0222513 A1
(43) Pub. Date: Jul. 4, 2024

(54) THIN FILM TRANSISTOR SUBSTRATE AND DISPLAY APPARATUS COMPRISING THE SAME

(71) Applicant: LG DISPLAY CO., LTD., SEOUL (KR)

(72) Inventors: Uyhyun CHOI, Gyeonggi-do (KR); Jaeman JANG, Gyeonggi-do (KR)

(73) Assignee: LG DISPLAY CO., LTD., SEOUL (KR)

(21) Appl. No.: 18/378,482

(22) Filed: Oct. 10, 2023

(30) Foreign Application Priority Data
Dec. 30, 2022 (KR) 10-2022-0190939

(51) Int. Cl. H01L 29/786; H01L 29/417; H01L 29/423; H10K 59/121

(52) U.S. Cl. CPC H01L 29/78645; H01L 29/41733; H01L 29/42324; H01L 29/42384; H01L 29/78633; H01L 29/78696; H10K 59/1213; H10K 59/1216

(57) ABSTRACT

A thin film transistor substrate and a display apparatus comprising the same include a substrate; an active layer disposed on the substrate; a first gate electrode disposed on the active layer; and a second gate electrode disposed on the active layer and disposed to be spaced apart from the first gate electrode; and a source electrode disposed on the active layer and connected to one side of the active layer and a drain electrode disposed on the active layer and connected to another side of the active layer, wherein the second gate electrode having a floating structure.

### CROSS-REFERENCE TO RELATED APPLICATION

This application claims the benefit of the Korean Patent Application No. 10-2022-0190939 filed on Dec. 30, 2022, which is hereby incorporated by reference as if fully set forth herein.

### BACKGROUND

### Field of the Disclosure

The present disclosure relates to a thin film transistor substrate and a display apparatus comprising the same.

### Description of the Background

Since thin film transistors may be manufactured on glass or plastic substrates, they are widely used as switching devices or driving devices for displays such as liquid crystal display devices or organic light emitting devices.

In general, it may be advantageous for switching thin film transistors used in display devices to have large on-current (Ion) to improve on-off characteristics, and for driving thin film transistors used in display devices to have large s-factors for gray scale expression.

However, since the on-current and the S-factor generally have a trade-off relationship, increasing the on-current tends to reduce the S-factor, and increasing the S-factor tends to reduce the on-current. Therefore, it is difficult to obtain a thin film transistor that may increase the on-current while having a large S-factor.

### SUMMARY

Accordingly, the present disclosure is directed to a thin film transistor substrate and a display apparatus comprising the same that substantially obviate one or more of problems due to limitations and disadvantages described above.

More specifically, the present disclosure to provide a thin film transistor substrate that has a large S-factor and increased on-current and a display apparatus comprising the same.

Additional features and advantages of the disclosure will be set forth in the description which follows and in part will be apparent from the description, or may be learned by practice of the disclosure. Other advantages of the present disclosure will be realized and attained by the structure particularly pointed out in the written description and claims hereof as well as the appended drawings.

To achieve these and other advantages and in accordance with the present disclosure, as embodied and broadly described, a display apparatus includes a substrate; an active layer disposed on the substrate; a first gate electrode disposed on the active layer; and a second gate electrode disposed on the active layer and disposed to be spaced apart from the first gate electrode; and a source electrode disposed on the active layer and connected to one side of the active layer and a drain electrode disposed on the active layer and connected to another side of the active layer, wherein the second gate electrode having a floating structure.

In another aspect of the present disclosure, a display apparatus includes a substrate; a first thin film transistor disposed on the substrate; and a second thin film transistor disposed on the substrate and having a structure different from that of the first thin film transistor, wherein the first film transistor includes: a first active layer disposed on the substrate; a first gate electrode disposed on the first active layer; a second gate electrode disposed on the first active layer and disposed to be spaced apart from the first gate electrode; and a first source electrode disposed on the first active layer and connected to one side of the first active layer and a first drain electrode disposed on the first active layer and connected to another side of the first active layer, and the second gate electrode has a floating structure.

It is to be understood that both the foregoing general description and the following detailed description are exemplary and explanatory and are intended to provide further explanation of the disclosure as claimed.

### BRIEF DESCRIPTION OF THE DRAWINGS

The accompanying drawings, which are included to provide a further understanding of the disclosure and are incorporated in and constitute a part of the disclosure, illustrate aspects of the disclosure and together with the description serve to explain the principle of the disclosure. In the drawings:

FIG. 1 is a plan view of a thin film transistor substrate according to an aspect of the present disclosure.

FIG. 2 is a cross-sectional view taken along I-I′ of the thin film transistor substrate shown in FIG. 1 according to an aspect of the present disclosure.

FIG. 3 is a cross-sectional view of a thin film transistor substrate having a light shielding layer according to an aspect of the present disclosure.

FIG. 4 is a plan view of a thin film transistor substrate according to another aspect of the present disclosure.

FIG. 5A is a cross-sectional view taken along I-I′ of the thin film transistor substrate shown in FIG. 4 according to another aspect of the present disclosure.

FIG. 5B is a cross-sectional view taken along I-I′ of the thin film transistor substrate shown in FIG. 4 according to another aspect of the present disclosure.

FIG. 6 is a plan view of a thin film transistor substrate according to another aspect of the present disclosure.

FIG. 7 is a cross-sectional view taken along II-II′ of the thin film transistor substrate shown in FIG. 6 according to another aspect of the present disclosure.

FIG. 8 is a plan view of a thin film transistor substrate according to another aspect of the present disclosure.

FIG. 9 is a cross-sectional view taken along II-II′ of the thin film transistor substrate shown in FIG. 8 according to an aspect of the present disclosure.

FIG. 10 is a cross-sectional view of the first film transistor and the second thin film transistor of the thin film transistor substrate according to an aspect of the present disclosure.

FIG. 11 is a cross-sectional view of a display apparatus including a thin film transistor substrate according to an aspect of the present disclosure.

FIG. 12 is a schematic diagram of a display apparatus according to an aspect of the present disclosure.

FIG. 13 is a circuit diagram for one pixel provided in a display apparatus according to an aspect of the present disclosure.

FIG. 14 is a circuit diagram for one pixel provided in a display apparatus according to another aspect of the present disclosure.

FIG. 15 is a circuit diagram for one pixel provided in a display apparatus according to another aspect of the present disclosure.

### DETAILED DESCRIPTION

Advantages and features of the present disclosure, and implementation methods thereof will be clarified through the following aspects, described with reference to the accompanying drawings. The present disclosure may, however, be embodied in different forms and should not be construed as being limited to the aspects set forth herein. Rather, these aspects are provided so that this disclosure will be thorough and complete, and will fully convey the scope of the present disclosure to those skilled in the art. Further, the present disclosure is only defined by the scope of the claims.

The shapes, sizes, ratios, angles, and numbers disclosed in the drawings for describing aspects of the present disclosure are merely examples, and thus the present disclosure is not limited to the illustrated details. Like reference numerals refer to like elements throughout. In the following description, when the detailed description of the relevant known function or configuration is determined to unnecessarily obscure the important point of the present disclosure, the detailed description will be omitted.

In the case in which “comprise,” “have,” and “include” described in the present specification are used, another part may also be present unless “only” is used. The terms in a singular form may include plural forms unless noted to the contrary.

In construing an element, the element is construed as including an error region although there is no explicit description thereof.

In describing a positional relationship, for example, when the positional order is described as “on,” “above,” “below,” “beneath”, and “next,” the case of no contact therebetween may be included, unless “just” or “direct” is used.

If it is mentioned that a first element is positioned “on” a second element, it does not mean that the first element is essentially positioned above the second element in the figure. The upper part and the lower part of an object concerned may be changed depending on the orientation of the object. Consequently, the case in which a first element is positioned “on” a second element includes the case in which the first element is positioned “below” the second element as well as the case in which the first element is positioned “above” the second element in the figure or in an actual configuration.

In describing a temporal relationship, for example, when the temporal order is described as “after,” “subsequent,” “next,” and “before,” a case which is not continuous may be included, unless “just” or “direct” is used.

It will be understood that, although the terms “first,” “second,” etc. may be used herein to describe various elements, these elements should not be limited by these terms. These terms are only used to distinguish one element from another. For example, a first element could be termed a second element, and, similarly, a second element could be termed a first element.

It should be understood that the term “at least one” includes all combinations related with any one item. For example, “at least one among a first element, a second element and a third element” may include all combinations of two or more elements selected from the first, second and third elements as well as each element of the first, second and third elements.

Features of various aspects of the present disclosure may be partially or overall coupled to or combined with each other, and may be variously inter-operated with each other and driven technically. The aspects of the present disclosure may be carried out independently from each other, or may be carried out together in a co-dependent relationship.

In the drawings, the same or similar elements are denoted by the same reference numerals even though they are depicted in different drawings.

In the aspects of the present disclosure, a source electrode and a drain electrode are distinguished from each other, for convenience of explanation. However, the source electrode and the drain electrode are used interchangeably. Thus, the source electrode may be the drain electrode, and the drain electrode may be the source electrode. Also, the source electrode in any one aspect of the present disclosure may be the drain electrode in another aspect of the present disclosure, and the drain electrode in any one aspect of the present disclosure may be the source electrode in another aspect of the present disclosure.

In one or more aspects of the present disclosure, for convenience of explanation, a source region is distinguished from a source electrode, and a drain region is distinguished from a drain electrode. However, aspects of the present disclosure are not limited to this structure. For example, a source region may be a source electrode, and a drain region may be a drain electrode. Also, a source region may be a drain electrode, and a drain region may be a source electrode.

FIG. 1 is a plan view of a thin film transistor substrate according to an aspect of the present disclosure.

As shown in FIG. 1, the thin film transistor substrate according to an aspect of the present disclosure may include a first active layer 120, a first gate electrode 141, a second gate electrode 142, a first source electrode 161 and a first drain electrode 162.

The first active layer 120 may be extended in a first direction, for example, in the horizontal direction. In this case, the first direction may be the direction in which the first source electrode 161 and the first drain electrode 162 face each other.

On one side, for example, the left side of the first active layer 120 is electrically connected to the first source electrode 161 through a first contact hole CH1, and another side, for example, the right side of the first active layer 120 is electrically connected to the first drain electrode 162 through a second contact hole CH2. On the other hand, it is not limited there to, the one side of the first active layer 120 may be connected to the first drain electrode 162, and the another side of the first active layer 120 may be connected to the first source electrode 161.

The first gate electrode 141 and the second gate electrode 142 may be formed to overlap with the first active layer 120. The first gate electrode 141 may overlap with a portion of the first active layer 120, and the second gate electrode 142 may overlap with another portion of the first active layer 120.

The first gate electrode 141 and the second gate electrode 142 are formed to face each other. And a direction in which the first gate electrode 141 and the second gate electrode 142 face each other may be same as the direction in which the first source electrode 161 and the first drain electrode 162 face each other.

The first gate electrode 141 and the second gate electrode 142 may be extended in a second direction, for example, in a vertical direction, and are formed to be spaced apart from each other over the first active layer 120.

One side of the first gate electrode 141 may be electrically connected to the driving part or other thin film transistor through an eighth contact hole CH8. For example, the one side of the first gate electrode 141 is electrically connected to a gate driver of the driving part or any one of a plurality of switching thin film transistor, and the second gate electrode 142 is formed in a floating structure, which is not electrically connected.

The thin film transistor according to an aspect of the present disclosure is provided with the first gate electrode 141 and the second gate electrode 142, thereby being possible to implement a thin film transistor with improved S-factor and on-current characteristics not degraded.

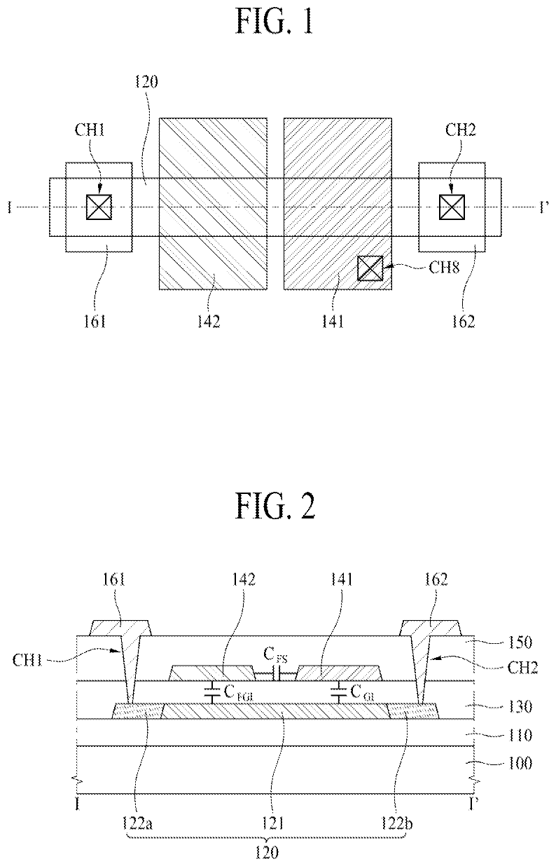

FIG. 2 is a cross-sectional view taken along I-I′ of a thin film transistor substrate shown in FIG. 1 according to an aspect of the present disclosure.

As shown in FIG. 2, the thin film transistor substrate according to an aspect of the present disclosure comprises a substrate 100; a buffer layer 110; a first active layer 120; a gate insulating layer 130; a first gate electrode 141; a second gate electrode 142; an interlayer insulating layer 150; a first source electrode 161 and a first drain electrode 162.

The substrate 100 may be made of glass or plastic. In particular, the substrate 100 may be made of a transparent plastic having flexible properties, for example polyimide. When the polyimide is used as the substrate 100, a heat resistant polyimide that may withstand high temperatures may be used, considering that the high temperature vapor deposition process is made on the substrate 100.

The buffer layer 110 is formed on the substrate 100. The buffer layer 110 may block air and moisture to protect the first active layer 120. The buffer layer 110 may be made of inorganic insulating layers such as silicone oxides, silicone nitrides, or metal oxides, but may be made of organic insulating layer, not necessarily limited thereto. The buffer layer 110 may be formed of a single layer or of a plurality of layers.

The first active layer 120 is formed on the buffer layer 110.

The first active layer 120 includes a first channel part 121, a first connection part 122a disposed on one side, for example, the left side of the first channel part 121 and a second connection part 122b disposed on another side, for example, the right side of the first channel part 121.

The first channel part 121 is made of a semiconductor material, and a portion of the first channel part 121 overlaps with the first gate electrode 141 and the second gate electrode 142, thereby may be protected by the first gate electrode 141 and the second gate electrode 142. On the other hand, another portion of the first channel part 121 is not protected by the first gate electrode 141 and the second gate electrode, so it may be protected through a separate mask during doping of the first active layer 120 and therefore, the another portion of the first channel part 121 may not have conductive properties.

The first connection part 122a and the second connection part 122b may have conductive properties through a conductive process of ion-doping a semiconductor material using the gate electrodes 141 and 142 or a separate mask.

The first connection part 122a and the second connection part 122b may not overlap with the first gate electrode 141 and the second gate electrode 142. The first connection part 122a and the second connection part 122b have superior conductivity compared to the first channel part 121, and each of them may serve as a wiring or source/drain electrode.

The first active layer 120 may comprise a semiconductor material, for example, an oxide semiconductor material. The oxide semiconductor material is, for example, at least one of IZO (InZnO)-based oxide semiconductor material, IGO (InGaO)-based oxide semiconductor material, ITO (InSnO)-based oxide semiconductor material, IGZO (InGaZnO)-based oxide semiconductor material, IGZTO (InGaZnSnO)-based oxide semiconductor material, GZTO (GaZnSnO)-based oxide semiconductor material, GZO (GaZnO)-based oxide semiconductor material, ITZO (InSnZnO)-based oxide semiconductor material and FIZO (FeInZnO)-based oxide semiconductor material.

The gate insulating layer 130 may be formed on the first active layer 120. Specifically, the gate insulating layer 130 is disposed on the first active layer 120 and the buffer layer 110 and also protects the first active layer 120.

The gate insulating layer 130 may include a silicon nitride layer (SiNx) or a silicon oxide layer (SiOx), but is not limited thereto. The gate insulating layer 130 may be formed of a single layer structure or of a plurality of layers structure.

The first gate electrode 141 and the second gate electrode 142 are formed on the gate insulating layer 130. In this case, since the gate insulating layer 130 is made of a dielectric material, a capacitance C_{GI} may be formed between the first gate electrode 141 and the first active layer 120, and a capacitance C_{FGI} may be formed between the second gate electrode 142 and the first active layer 120.

The first gate electrode 141 and the second gate electrode 142 are formed over the first active layer 120 and do not overlap with each other. In addition, the first gate electrode 141 and the second gate electrode 142 may be formed on the same layer, specifically on the gate insulating layer 130. Furthermore, the interlayer insulating layer 150 of the dielectric material may be provided between the first gate electrode 141 and the second gate electrode 142, therefore, a capacitance C_{FS} may be formed between the first gate electrode 141 and the second gate electrode.

The first gate electrode 141 and the second gate electrode 142 may be formed of the same material in the same process. But it is not limited thereto.

The first gate electrode 141 and the second gate electrode 142 may include at least one of aluminum-based metals such as aluminum Al or aluminum alloy, silver-based metals such as silver Ag or silver alloy, copper-based metals such as copper Cu or copper alloy, molybdenum-based metals such as molybdenum Mo or molybdenum alloy, tantalum Ta, neodymium Nd and titanium Ti. The first gate electrode 141 and the second gate electrode 142 may have a multilayer structure including at least two different conductive layers.

As shown in FIG. 2, the first gate electrode 141 and the second gate electrode 142 may be arranged in a row on the gate insulating layer 130. In this case, the first gate electrode 141 may be formed adjacent to the first drain electrode 162, and the second gate electrode 142 may be formed adjacent to the first source electrode 161. However, it is not limited thereto, and the first gate electrode 141 may be adjacent to the first source electrode 161 and the second gate electrode 142 may be formed to be adjacent to the first drain electrode 162.

The first gate electrode 141 may be electrically connected to the gate driver to receive a predetermined gate signal from the gate driver. Therefore, a channel may be formed in the first active layer 120 by a voltage VG applied through the first gate electrode 141, and the thin film transistor according to an aspect of the present disclosure may be turned on.

The second gate electrode 142 has a floating structure. Therefore, unlike the first gate electrode 141, the second gate electrode 142 is not electrically connected.

However, the second gate electrode 142 may be charged by the voltage VG applied to the first gate electrode 141. The second gate electrode 142 may be charged to have an electrical property, thereby forming a channel in a portion of the first active layer 120 overlapping with the second gate electrode 142.

When the voltage is applied to the first gate electrode 141, the second gate electrode 142 may be charged and a predetermined voltage may be applied. If a voltage of V1 is applied to the first gate electrode, the second gate electrode 142 may be charged with a voltage of V2 that satisfies the following [Equation 1].

$$V 2 = V 1 \times CR 1 \qquad [ Equation 1 ]$$

In this case, CR1=C_{FS}/(C_{FS}+C_{FGI}), the C_{FS} refers to a capacitance formed between the first gate electrode 141 and the second gate electrode 142, and the C_{FGI} refers to a capacitance formed between the second gate electrode 142 and the first active layer 120.

Since the denominator of CR1 of [Equation 1] is larger than the numerator, the voltage V2 applied to the second gate electrode 142 is formed smaller than the voltage V1 applied to the first gate electrode 141.

Therefore, according to an aspect of present disclosure, even if the voltage V2 applied to the second gate electrode 142 is lower than the voltage V1 applied to the first gate electrode 141, the on-current properties of the active layer 120 may not be lowered by the voltage V1 applied to the first gate electrode 141.

In addition, the electric field affecting the first active layer 120 may be an electric field formed by the first gate electrode 141 and an electric field formed by the second gate electrode 142. In this case, since the voltage V2 applied to the second gate electrode 142 is formed to be smaller than the voltage V1 applied to the first gate electrode 141, the S-Factor of the thin film transistor substrate according to an aspect of present disclosure may be raised.

The sub-threshold swing S-factor may be used as an indicator of the degree of change in the drain-source current IDS to the gate voltage VGS in the threshold voltage Vth section of the thin film transistor.

Such an S-factor is obtained as the reciprocal value of the slope of the graph in the threshold voltage Vth section in the drain-source current graph for the gate voltage of the thin film transistor. Therefore, when the S-factor increases, the drain-source current change rate for the gate voltage becomes gentle in the threshold voltage Vth section, and when the S-factor decreases, the drain-source current change rate for the gate voltage increases rapidly in the threshold voltage Vth section. In other words, if the slope of the drain-source current graph is large, the S-factor is small, and if the slope of the drain-source current graph is small, the S-factor is large.

When the S-factor increases, the change rate of the drain-source current to the gate voltage in the threshold voltage Vth section becomes gentle, so it becomes easy to adjust the magnitude of the drain-source current through the adjustment of the gate voltage. In a display apparatus driven by current, for example, an organic light emitting display device, a gray scale of a pixel may be controlled by adjusting the magnitude of the drain-source current of the driving thin film transistor. In this case, the magnitude of the drain-source current of the driving thin film transistor is determined by the gate voltage. Therefore, in an organic light emitting display apparatus driven by current, the larger the S-factor of the driving thin film transistor (driving TFT), the easier it is to adjust the gray scale of the pixel.

Since the thin film transistor according to an aspect of present disclosure includes the first gate electrode 141 and the second gate electrode 142, the thin film transistor according to an aspect of present disclosure may have an increased S-factor characteristic and a large on—current characteristic. As a result, the thin film transistor according to an aspect of present disclosure may have excellent gray scale expression ability and excellent current characteristics.

The interlayer insulating layer 150 is formed on the first gate electrode 141 and the second gate electrode 142.

The interlayer insulating layer 150 insulates the first gate electrode 141 and second gate electrode and 142 from the first source electrode 161, and further, insulates the first gate electrode 141 and the second gate electrode 142 from the first drain electrode 162. The interlayer insulating layer 150 may be made of a single layer or a plurality of layers comprising inorganic insulating layers and/or organic insulating layers.

The interlayer insulating layer 150 is provided with a first contact hole CH1 and a second contact hole CH2. Accordingly, one side, for example, the left side of the first active layer 120 may be exposed by the first contact hole CH1, and another side, for example, the right side of the first active layer 120 may be exposed by the second contact hole CH2.

The first source electrode 161 and the first drain electrode 162 may be formed on the interlayer insulating layer 150.

The first source electrode 161 is electrically connected to the one side of the first active layer 120, and the first drain electrode 162 is electrically connected to the another side of the first active layer 120.

Specifically, the first source electrode 161 is connected to the one side of the first active layer 120 through the first contact hole CH1 provided in the interlayer insulating layer 150, and the first drain electrode 162 is connected to the another side of the first active layer 120 through the second contact hole CH2 provided in the interlayer insulating layer 150.

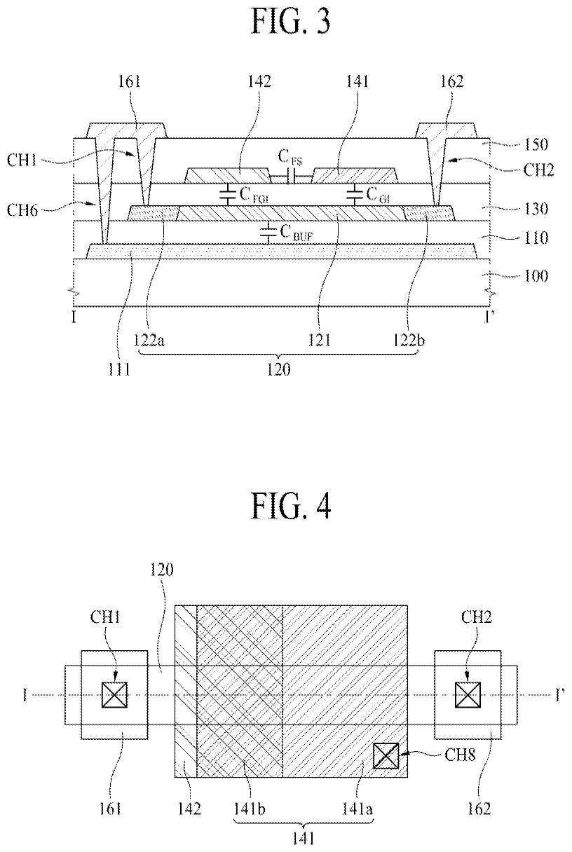

FIG. 3 is a cross-sectional view of a thin film transistor substrate having a light-shielding layer according to an aspect of the present disclosure.

The thin film transistor substrate of the present disclosure according to FIG. 3 is the same as the thin film transistor substrate according to FIG. 2, except that the light shielding layer 111 is further included, so only different configurations will be described below.

The light shielding layer 111 may be formed on the substrate 100. on the other hand, although not illustrated, a lower buffer layer may be formed between the substrate 100 and the light shielding layer 111, and the light shielding layer 111 may be formed on the lower buffer layer.

By overlapping with the first channel part 121 of the first active layer 120, the light shielding layer 111 may protect the first channel part 121 of the first active layer 120 by blocking light incident from the lower part of the substrate 100.

The light shielding layer 111 may include one of at least an aluminum-based metal such as an aluminum Al or aluminum alloy, a silver-based metal such as silver Ag or silver alloys, a copper-based metal such as copper Cu or copper alloys, molybdenum-based metal such as molybdenum Mo or molybdenum alloys, chromium Cr, tantalum Ta, neodymium Nd, and titanium Ti.

The light shielding layer 111 may be electrically connected to the first source electrode 161 through a 6th contact hole CH6. By forming as described above, a voltage difference may occur between the first active layer 120 and the light shielding layer 111. Furthermore, since the buffer layer 110 formed between the first active layer 120 and the light shielding layer 111 includes a dielectric material, a capacitance C_{BUF} may be formed between the light shielding layer 111 and the first active layer 120.

By forming the capacitance C_{BUF}, the thin film transistor according to an aspect of the present disclosure may further improve the S-factor.

Specifically, by the capacitance C_{BUF} formed between the light shielding layer 111 and the first active layer 120, the field reduction effect on the first active layer 120 is further increased. Thus, the thin film transistor S-factor according to an aspect of the present disclosure may be further be increased.

FIG. 4 is a plan view of a thin film transistor substrate according to another aspect of the present disclosure.

The thin film transistor substrate according to FIG. 4 is the same as the thin film transistor substrate according to FIG. 1, except that the first gate electrode 141 is extended in a direction of the second gate electrode 142, so only different configurations will be described below.

According to another aspect of the present disclosure, the first gate electrode 141 may include a body part 141a and an extension part 141b.

The extension part 141b may be formed to overlap with a portion of or the entire the second gate electrode 142, while extending in a direction in which the second gate electrode 142 formed.

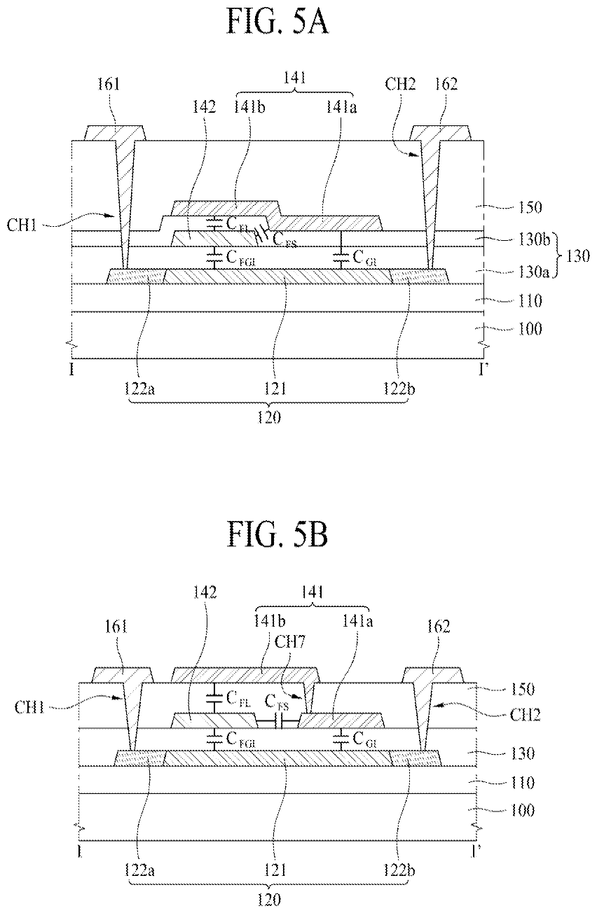

FIG. 5A is a cross-sectional view taken along I-I′ of a thin film transistor substrate shown in FIG. 4 according to another aspect of the present disclosure.

According to another aspect of the present disclosure, the aspect according to FIG. 5A is the same as the aspect according to FIG. 2, except that the first gate electrode 141 includes a body part 141a and an extension part 141b, and the gate insulating layer 130 includes a first gate insulating layer 130a and a second gate insulating layer 130b. So only different configurations will be described below.

The gate insulating layer 130 may include a first gate insulating layer 130a and a second gate insulating layer 130b.

In this case, the first gate insulating layer 130a is formed on the first active layer 120. In this case, the first gate insulating layer 130a may be the same configuration as the gate insulating layer 130 according to an aspect of FIG. 2.

According to the another aspect of the present disclosure, the second gate insulating layer 130b is formed on the first gate insulating layer 130a and the second gate electrode 142. Therefore, the first gate insulating layer 130a and the second gate insulating layer 130b may be formed as a structure covering the second gate electrode 142, thereby, the second gate electrode 142 may be formed to have a floating structure.

According to an aspect of the present disclosure, the first gate electrode 141 is formed on the second gate insulating layer 130b. Therefore, the first gate electrode 141 and the second gate electrode 142 are provided on different layers.

Therefore, since the first gate electrode 141 includes the body part 141a and the extension part 142b, the entire channel part 121 of the first active layer 120 may overlap with the first gate electrode 141. Meanwhile, a portion of the first channel part 121 of the first active layer 120 may overlap with the second gate electrode 142.

The first gate electrode 141 is formed on the second gate insulating layer 130b. In this case, the body part 141a of the first gate electrode 141 does not overlap with the second gate electrode 142, and the extension part 142b of the first gate electrode 141 may overlap with the second gate electrode 142 above the second gate electrode 142.

Since the second gate insulating layer 130b comprising a dielectric material is provided between the extension part 141b and the second gate electrode 142, a capacitance C_{FL} formed between the extension part 141b and the second gate electrode 142 is further formed.

According to an aspect of the present disclosure, since the extension part 141b overlaps with the second gate electrode 142, the capacitance C_{FS} formed between the body part 141a and the second gate electrode 142 and the capacitance C_{HL} formed between the extension part 141b and the second gate electrode 142 are connected in parallel.

According to an aspect of the present disclosure, a voltage V2 applied to the second gate electrode 142 is shown in [Equation 2].

$$V 2 = CR 2 \times V 1 \qquad [ Equation 2 ]$$

$$In this case ,$$

$$CR 2 = ( {C}_{FL} + {C}_{FS} ) / ( {C}_{FL} + {C}_{FS} + {C}_{FGI} )$$

Since the denominator of the CR2 of [Equation 2] is larger than the numerator, the voltage V2 applied to the second gate electrode 142 is formed smaller than the voltage V1 applied to the first gate electrode 141. Since a channel is formed on the first active layer 120 by an electric field formed by the first gate electrode 141 and an electric field formed by the second gate electrode 142, the thin film transistor substrate according to an aspect of present disclosure may obtain an increased S-factor without degrading on-current characteristics.

According to an aspect of the present disclosure, by adjusting the thickness of the second gate insulating layer 130b, the capacitance C_{FS} and C_{FL} formed between the first gate electrode 141 and the second gate electrode 142 may be adjusted.

Specifically, as the thickness of the second gate insulating layer 130b decreases, the capacitance C_{FS} and C_{FL} may be increased, and accordingly, the voltage V2 applied to the second gate electrode 142 may be increased.

In addition, according to an aspect of the present disclosure, by adjusting the length of the extension part 141b of the first gate electrode 141, the capacitance C_{FL} formed between the extension part 141b of the first gate electrode 141 and the second gate electrode 142 may be adjusted.

Specifically, the capacitance C_{FL} is proportional to the length of the extension portion 141b. Therefore, as the length of the extension part 141b increases, the capacitance C_{HL} may be increased, and accordingly, the voltage V2 applied to the second gate electrode 142 may be increased.

As a result, according to an aspect of the present disclosure, by adjusting the thickness of the second gate insulating layer 130b, or by adjusting the length of the extension part 141b of the first gate electrode 141, the voltage V2 applied to the second gate electrode 142 may be adjusted, and the S-factor of the thin film transistor may be adjusted according to device characteristics.

FIG. 5B is a cross-sectional view taken along I-I′ of a thin film transistor substrate shown in FIG. 4 according to another aspect of the present disclosure.

The aspect according to FIG. 5B is the same as the aspect of FIG. 5A except that the second gate insulating layer 130b is not provided and the structure of the extension part 141b of the first gate electrode 141 is changed, and thus different configurations will be mainly described below.

According to the aspect of FIG. 5B, the second gate electrode 142 and the body part 141a of the first gate electrode 141 may be formed on the same layer, specifically, on the gate insulating layer 130 through the same process, unlike FIG. 5A.

The interlayer insulating layer 150 is formed on body part 141a of the first gate electrode 141 and the second gate electrode 142 and is provided with a seventh contact hole CH7 that exposes a portion of the body part 141a of the first gate electrode 141. The body part 141a and the extension part 141b may be electrically connected through the seventh contact hole CH7.

The extension part 141b of the first gate electrode 141 is provided on the interlayer insulating layer 150 and may be formed in the same layer as the first source electrode 161 and the first drain electrode 162.

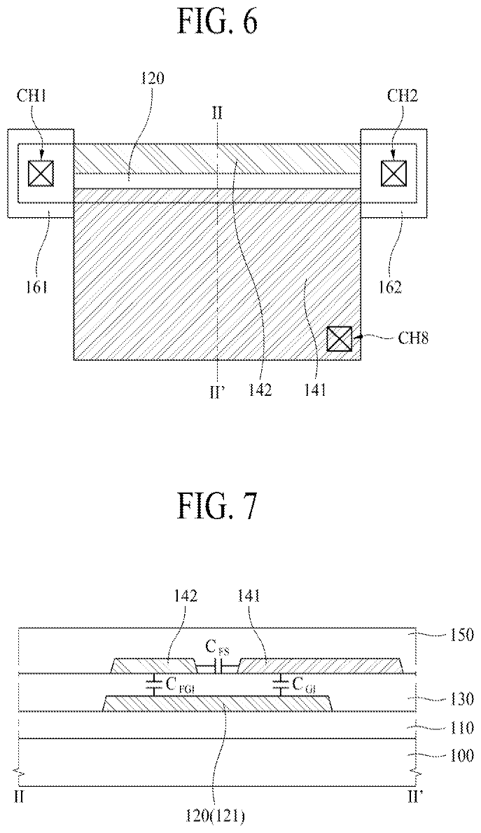

FIG. 6 is a plan view of a thin film transistor substrate according to another aspect of the present disclosure.

In this case, the thin film transistor substrate according to FIG. 6 is the same as the thin film transistor substrate according to FIG. 1, except for the direction in which the first gate electrode 141 and the second gate electrode 142 are formed, so different configurations will be mainly described below.

According to the aspect of the present disclosure, the first gate electrode 141 and the second gate electrode 142 face each other in the second direction, for example, in the vertical direction, and are formed on the first active layer 120. Specifically, the direction in which the first gate electrode 141 and the second gate electrode 142 face each other and the direction in which the first source electrode 161 and the first drain electrode 162 face each other may be orthogonal to each other.

The first gate electrode 141 may overlap with one side, for example, the lower side of the first active layer 120 and the second gate electrode 142 may overlap with another side, for example, the upper side of the first active layer 120.

The first gate electrode 141 may extend in the vertical direction, and may extend downward, for example, based on the first active layer 120. In this case, the first gate electrode 141 does not overlap with the second gate electrode 142.

According to an aspect of the present disclosure, one end, for example the upper end of the second gate electrode 142 may be formed to match one end, for example, the upper end of the first active layer 120. On the other hand, it is not limited thereto, the second gate electrode 142 may be extended in the vertical direction, and may be extended upward based on the first active layer 120.

FIG. 7 is a cross-sectional view taken along II-II′ of a thin film transistor substrate shown in FIG. 6 according to another aspect of the present disclosure.

As shown in FIG. 7, the buffer layer 110 is formed on the substrate 100, the first active layer 120 is formed on the buffer layer 110, the gate insulating layer 130 is formed on the first active layer 120, the first gate electrode 141 and the second gate electrode 142 are formed to be space apart from each other on the gate insulating layer 130, and the interlayer insulating layer 150 is formed on the first gate electrode 141 and the second gate electrode 142.

The first gate electrode 141 may extend in one direction with respect to the channel portion 121. For example, the first gate electrode 141 may be formed by extending to the outside of the first active layer 120 past one end, for example, the right end of the first active layer 120.

The second gate electrode 142 may be formed by extending it in the other side of the channel part 121. For example, the second gate electrode 142 is formed to match another end, for example, the left end of the first active layer 120 and may be formed so that it is not extended to the outside of the first active layer 120. However, it is not limited thereto, and the second gate electrode 142 may extend to an outer periphery of the first active layer 120.

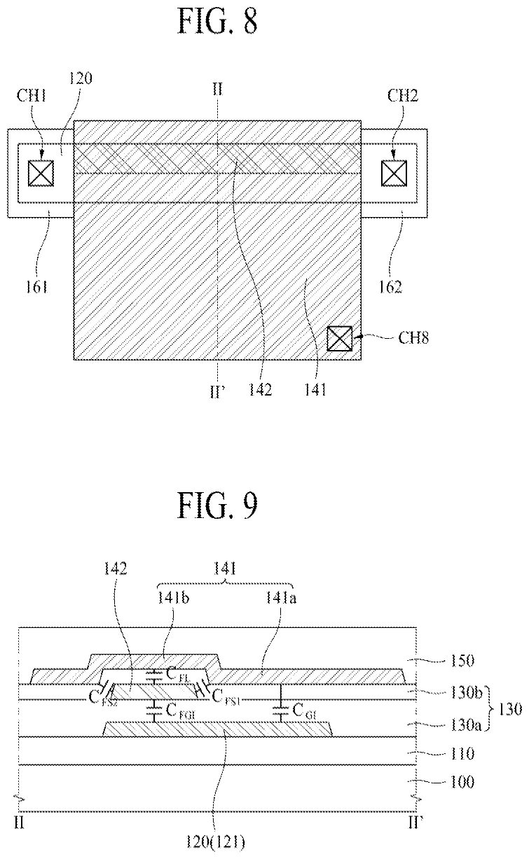

FIG. 8 is a plan view of a thin film transistor substrate according to another aspect of the present disclosure.

The thin film transistor substrate according to FIG. 8 is the same as the thin film transistor substrate according to FIG. 6 except for the first gate electrode 141, so different configurations will be mainly described below.

According to FIG. 8, the first gate electrode 141 may extend in a vertical direction, specifically, in a direction orthogonal to the direction in which the first source electrode 161 and the first drain electrode 162 face each other.

According to an aspect of the present disclosure, the first gate electrode 141 may extend in a vertical direction with respect to the first active layer 120. For example, the first gate electrode 141 may extend in an upward and downward direction of the first active layer 120.

The first gate electrode 141 may extend in a vertical direction to cover the second gate electrode 142. As a result, capacitance formed between the first gate electrode 141 and the second gate electrode 142 may be increased. The capacitance formed between the first gate electrode 141 and the second gate electrode 142 will be described in detail with reference to FIG. 9.

FIG. 9 is a cross-sectional view taken along II-II′ of a thin film transistor substrate shown in FIG. 8 according to an aspect of the present disclosure.

The thin film transistor substrate according to FIG. 9 is the same as the thin film transistor substrate according to FIG. 7 except that the first gate electrode 141 is formed by extending in the direction of the second gate electrode 142. In addition, the thin film transistor substrate according to FIG. 9 is the same as the thin film transistor substrate according to FIG. 5A, except for the configuration of the extension part 141b of the first gate electrode 141, so different configurations will be mainly described below.

As shown in FIG. 9, as described in FIG. 5A, a capacitance C_{FSI} may be formed between the body part 141a of the first gate electrode 141 and the second gate electrode 142.

The extension part 141b of the first gate electrode 141 may extend in the direction of the second gate electrode 142 and overlap with the second gate electrode 142. On the other hand, unlike the aspect according to FIG. 5A, according to an aspect of FIG. 9, the extension part 141b of the first gate electrode 141 may be further extended to be formed on the second gate insulating layer 130b on which the second gate electrode 142 is not formed.

As shown in FIG. 9, the extension part 141b may form capacitance C_{HL} and C_{FS2} on the upper and side surfaces of the second gate electrode 142, respectively.

Since the first gate electrode 141 is extended in the direction of the second gate electrode 142, the capacitances C_{FSI}, C_{FL} and C_{FS2} may be formed between the first gate electrode 141 and the second gate electrode 142.

The capacitances C_{FSI}, C_{FL}, and C_{FS2} are formed between the first gate electrode 141 and the second gate electrode 142, so that a voltage V2 applied to the second gate electrode 142 by charged by a voltage applied to the first gate electrode 141 may be defined as [Equation 3].

$$V 2 = V 1 \times CR 3 \qquad [ Equation 3 ]$$

$$In this case ,$$

$$CR 3 = ( {C}_{FL} + {C}_{FS 1} + {C}_{FS 2} ) / ( {C}_{FL} + {C}_{FS 1} + {C}_{FS 2} + {C}_{FGI} )$$

Since the denominator of the CR3 of [Equation 3] is larger than the numerator, the voltage V2 applied to the second gate electrode 142 is formed smaller than the voltage V1 applied to the first gate electrode 141. Since the electric field on the first active layer 120 is divided according to the first gate electrode 141 and the second gate electrode 142, a thin film transistor according to the aspect of the present disclosure may obtain an improved S-factor without degrading on-current characteristics.

In the same as described in FIG. 5A, by adjusting the length of the extension of the extension part 141b and the thickness of the second gate insulating layer 130b, and the S-factor of the thin film transistor according to the aspect of present disclosure may be adjusted according to device characteristics.

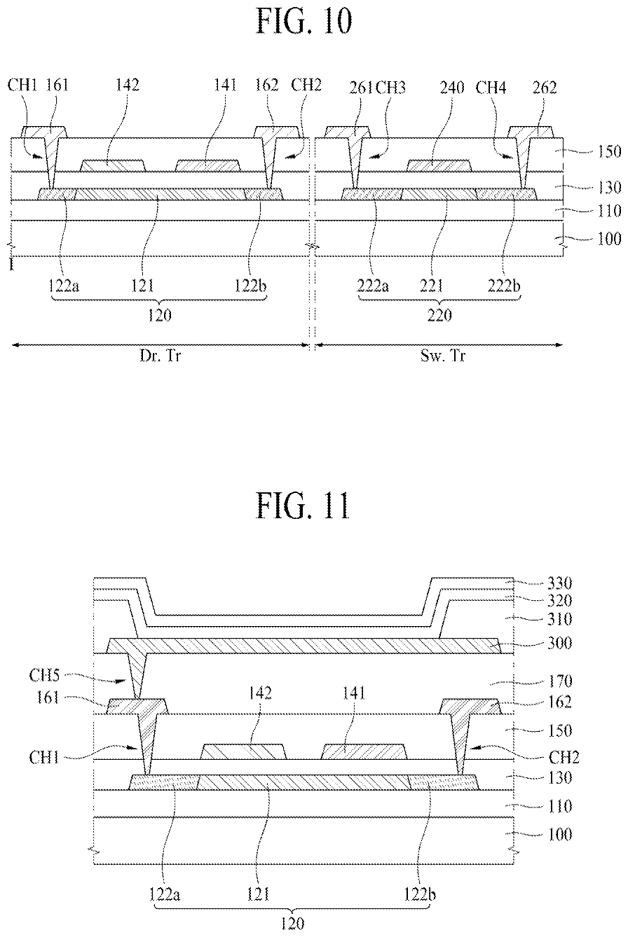

FIG. 10 is a cross-sectional view of the first film transistor and the second thin film transistor of the thin film transistor substrate according to an aspect of the present disclosure.

A display apparatus may include a display area A/A and a non-display area NDA.

Furthermore, the display area A/A may include a plurality of pixels, and the non-display area NDA may include a gate drive circuit GIP.

One pixel of the plurality of pixels includes a plurality of thin film transistors, and the plurality of thin film transistors may include a driving thin film transistor and a switching thin film transistor. In addition, the plurality of thin film transistors may be included in the gate drive circuit GIP.

The one pixel of the plurality of pixels may include a first thin film transistor T1, and another pixel of the plurality of pixels may include a second thin film transistor T2. In this case, the first thin film transistor T1 and the second thin film transistor T2 may have different structure. Furthermore, one of the plurality of thin film transistors provided in the one of the plurality of pixels may be the first thin film transistor T1, and another thin film transistor may be a second thin film transistor T2.

According to the aspect of the present disclosure, as shown in FIG. 10, the thin film transistor substrate may include the first thin film transistor T1 and the second thin film transistor T2.

The first thin film transistor T1 may be the thin film transistors according to an aspect of the present disclosure, and the first thin film transistor T1 includes a substrate 100, a buffer layer 110 provided on the substrate 100, an first active layer 120 including a first channel part 121, a first connection part 122a provided on one side of the first channel part 121, and a second connection part 122b provided on another side of the channel part 121, a gate insulating layer 130 provided on the first active layer 120, a first gate electrode 141 and a second gate electrode 142 provided on the gate insulating layer 130, an interlayer insulating layer 150 provided on the first gate electrode 141 and the second gate electrode 142, a first source electrode 161 provided on the interlayer insulating layer 150 and connecting to the first connection part 122a through a first contact hole CH1 and a first drain electrode 162 provided on the interlayer insulating layer 150 and connecting to the second connection part 122b through a second contact hole CH2.

On the other hand, according to an aspect of the present disclosure, The second thin film transistor T2 includes a substrate 100, a buffer layer 110 provided on the substrate 100, a second active layer 220 including a second channel part 221, a first connection part 222a on one side of the second channel part 221, and a second connection part 222b on another side of the second channel part 221, a gate insulating layer 130 provided on the second active layer 220, a third gate electrode 240 provided on the gate insulating layer 130, an interlayer insulating layer 150 provided on the third gate electrode 240, a second source electrode 261 provided on the interlayer insulating layer 150 and connecting to the first connection part 222a through a third contact hole CH3 and a second drain electrode 262 provided on the interlayer insulating layer 150 and connecting to the second connection part 222b through a fourth contact hole CH4.

According to an aspect of the present disclosure, the number of gate electrodes provided in the first film transistor TI may be more than the number of gate electrodes provided in the second film transistor T2. For example, the first thin film transistor TI includes the first gate electrode 141 and the second gate electrode 142, and the second thin film transistor T2 includes the third gate electrode 240. Therefore, the number of gate electrodes provided in the first thin film transistor T1 is more than the number of gate electrodes provided in the second thin film transistor T2

According to an aspect of the present disclosure, the first gate electrode 141 and the second gate electrode 142 of the first thin film transistor T1 and the third gate electrode 240 of the second thin film transistor T2 may all be formed on the same layer, specifically on the gate insulating layer 130.

According to an aspect of the present disclosure, the first thin film transistor T1 and the second film transistor T2 are made of different structures, so that the first thin film transistor T1 may be provided in a structure for improving an S-factor, and the second thin film transistor T2 may be provided in a structure for improving an on-current. As a result, a thin film transistor substrate suitable for the purpose of the device may be implemented.

It is desirable that the driving thin film transistor facilitates gray scale expression through the increase of the S-factor, and the switching thin film transistor has high on-current characteristics. Therefore, according to an aspect of present disclosure, the driving thin film transistor may be formed of the first thin film transistor T1, and the switching thin film transistor may be formed of the second thin film transistor T2.

According to an aspect of the present disclosure, the driving thin film transistor consisting of the first thin film transistor T1 may obtain an improved S-factor so that it is easy to express the gray scale without degrading on-current characteristics.

FIG. 11 is a cross-sectional view of a display apparatus including a thin film transistor substrate according to an aspect of the present disclosure.

As shown in FIG. 11, a display apparatus according to an aspect of the present disclosure includes a substrate 100, a buffer layer 110, a first active layer 120, a gate insulating layer 130, a first gate electrode 141, a second gate electrode 142, a interlayer insulating layer 150, a first source electrode 161, a first drain electrode 162, a planarization layer 170, a first electrode 300, a bank layer 310, a light emitting layer 320, and a second electrode 330.

The substrate 100, the buffer layer 110, the first active layer 120, the gate insulating layer 130, the first gate electrode 141, the second gate electrode 142, the interlayer insulating layer 150, the first source electrode 161 and the first drain electrode 162 are the same as the aspects described above, so different configurations will be mainly described below.

The planarization layer 170 is provided on the first source electrode 161 and the first drain electrode 162. A fifth contact hole CH5 is provided in the planarization layer 170, and a portion of the first source electrode 161 is exposed by the fifth contact hole CH5. In some cases, however, a portion of the first drain electrode 162 may be exposed by the fifth contact hole CH5.

The first electrode 300 is formed on the planarization layer 170 and is connected to the first source electrode 161 or the first drain electrode 162 through the fifth contact hole CH5. The first electrode 300 may function as an anode.

The bank layer 310 is provided to cover the edge of the first electrode 300 to define the light emitting area. Therefore, an upper surface area of the first electrode 300, which is exposed without hidden by the bank layer 310, becomes the light emitting area.

The light emitting layer 320 is provided on the first electrode 300. The light emitting layer 320 may consist of a red, green, and blue emission layer patterned for each pixel, or may consist of a white emission layer connected to all pixels. When the light emitting layer 320 is made of a white light emission layer, the light emitting layer 320 may include, for example, a first stack including a blue light emission layer, a second stack including a yellow green light emission layer, and a charge generation layer provided between the first stack and the second stack.

The second electrode 330 is provided on the light emitting layer 320. The second electrode 330 may function as a cathode.

Although not shown, an encapsulation layer may be formed to prevent the penetration of moisture or oxygen on the second electrode 330.

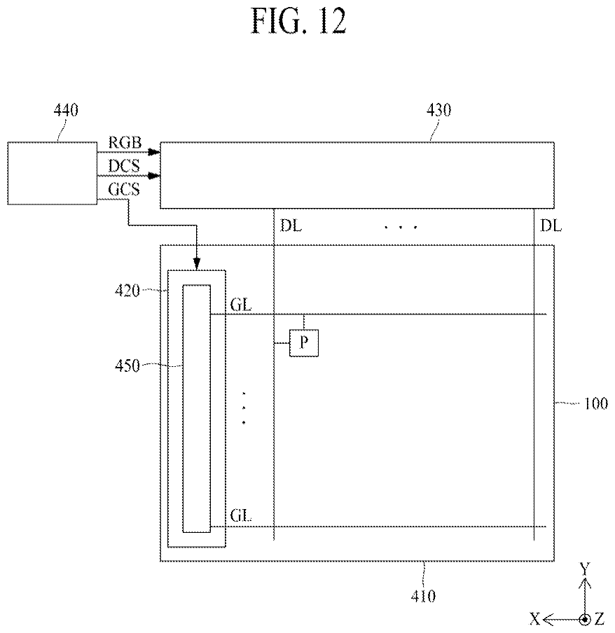

FIG. 12 is a schematic diagram of a display apparatus according to an aspect of the present disclosure.

As shown in FIG. 12, the display apparatus according to an aspect of the present disclosure may include a display panel 410, a gate driver 420, a data driver 430, and a controller 440.

The display panel 410 includes gate lines GLs and data lines DLs, and pixels P are disposed in respective crossing areas of the gate lines GLs and data lines DLs. An image is displayed by driving the pixel P. The gate lines GLs, the data lines DLs, and the pixels P may be disposed on the substrate 100.

The controller 440 controls the gate driver 420 and the data driver 430. The controller 440 outputs a gate control signal GCS for controlling the gate driver 420 and a data control signal DCS for controlling the data driver 430 by using a signal supplied from an external system (not shown). Also, the controller 440 samples input video data input from the external system and rearranges the sampled input video data, and supplies the rearranged digital video data RGB to the data driver 430.

The gate control signal GCS includes a gate start pulse GSP, a gate shift clock GSC, a gate output enable signal GOE, a start signal Vst, and a gate clock GCLK. Further, control signals for controlling a shift register may be included in the gate control signal GCS.

The data control signal DCS includes a source start pulse SSP, a source shift clock signal SSC, a source output enable signal SOE, and a polarity control signal POL.

The data driver 430 supplies a data voltage to the data lines DL of the display panel 410. Specifically, the data driver 430 converts the video data RGB inputted from the controller 440 into an analog data voltage and supplies the data voltage to the data lines DL.

The gate driver 420 may be mounted on the display panel 410. As described above, a structure in which the gate driver 420 is directly mounted on the display panel 410 is referred to as a gate-in-panel (GIP) structure. Specifically, in the gate-in-panel (GIP) structure, the gate driver 420 may be disposed on the substrate 100.

The gate driver 420 may include a shift register 450.

The shift register 450 sequentially supplies gate pulses to the gate lines GL during one frame by the use of start signal and gate clock transmitted from the controller 440. Herein, the one frame refers to a period in which one image is outputted through the display panel 410. The gate pulse has a turn-on voltage capable of turning on a switching device (thin film transistor) disposed in the pixel P.

Also, during the remaining period of one frame, in which the gate pulse is not supplied, the shift register 450 supplies a gate-off signal capable of turning off the switching device to the gate line GL. Hereinafter, the gate pulse and the gate-off signal are totally referred to as a scan signal GS.

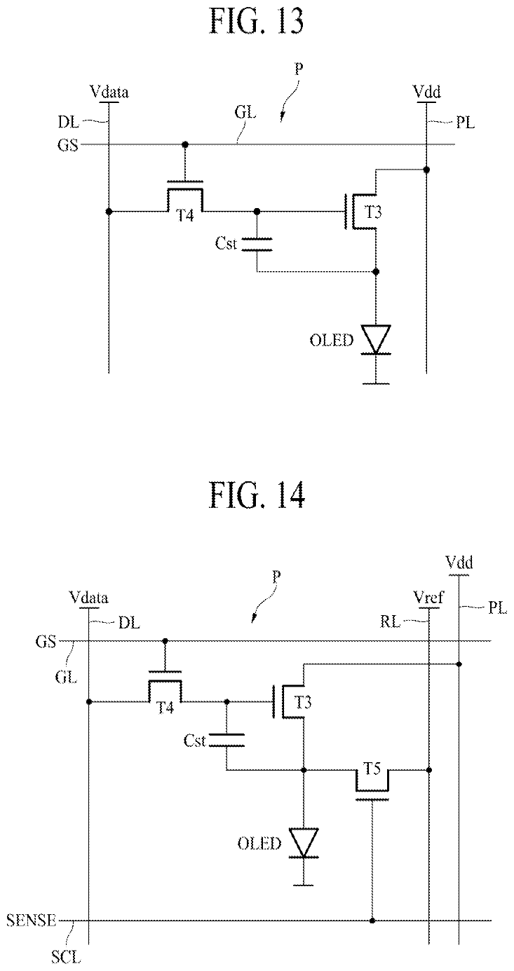

FIG. 13 is a circuit diagram of one pixel provided in a display apparatus according to an aspect of the present disclosure.

As shown in FIG. 13, the display apparatus according to an aspect of present disclosure includes third and fourth thin film transistors T3 and T4 and capacitors Cst.

The third thin film transistor T3 is a driving thin film transistor, and the fourth thin film transistor T4 is a switching thin film transistor. At least one of the third thin film transistor T3 and the fourth thin film transistor T4 may be formed of the above-described various thin film transistors.

The third thin film transistor T3 is switched according to the data voltage Vdata supplied from the fourth thin film transistor T4, generates a data current from the driving voltage Vdd supplied from the power line PL, and supplies it to the organic light emitting diode OLED.

The fourth thin film transistor T4 is switched according to the gate signal GS supplied to the gate line GL and supplies the data voltage Vdata supplied from the data line DL to the third thin film transistor T3.

The capacitor Cst serves to maintain the data voltage supplied to the third thin film transistor T3 for one frame, and is provided between the gate electrode and the source electrode of the third thin film transistor T3.

The organic light emitting diode OLED emits predetermined light according to a data current supplied from the third thin film transistor T3.

Meanwhile, when the third thin film transistor T3 includes the third thin film transistor T3 according to an aspect of present disclosure, the gate electrode provided in the third thin film transistor T3 may be connected to the source electrode of the switching thin film transistor T4 to receive the data voltage Vdata supplied from the switching thin film transistor T4. Alternatively, the gate electrode and the source electrode may form the capacitor Cst.

FIG. 14 is a circuit diagram of one pixel provided in a display apparatus according to another aspect of the present disclosure.

As shown in FIG. 14, the display apparatus according to another aspect of present disclosure includes third to fifth thin film transistors T3, T4, T5 and a capacitor Cst.

The third thin film transistor T3 is a driving thin film transistor, and the fourth and fifth thin film transistors T4 and T5 are switching thin film transistors. At least one of the third to fifth thin film transistors T3, T4, and T5 may be formed of the above-described various thin film transistors.

The third thin film transistor T3 is switched according to the data voltage Vdata supplied from the fourth thin film transistor T4, generates a data current from the driving voltage Vdd supplied from the power line PL, and supplies it to the organic light emitting diode OLED.

The fourth thin film transistor T4 is switched according to the gate signal GS supplied to the gate line GL and supplies the data voltage Vdata supplied from the data line DL to the third thin film transistor T3.

The fifth thin film transistor T5 supplies the current of the third thin film transistor T3 to the reference line RL in response to the sensing control signal SENSE supplied from the scan line SCL. A reference voltage Vref is supplied to the reference line RL.

The capacitor Cst serves to maintain the data voltage supplied to the third thin film transistor T3 for one frame, and is provided between the gate electrode and the source electrode of the third thin film transistor T3.

The organic light emitting diode OLED emits predetermined light according to a data current supplied from the third thin film transistor T3.

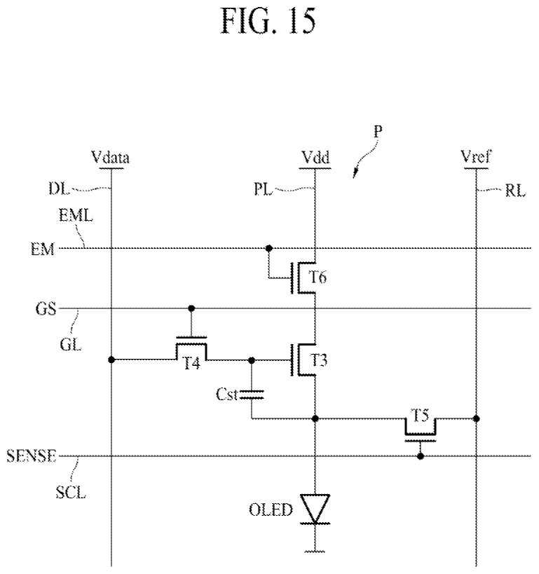

FIG. 15 is a circuit diagram of one pixel provided in a display apparatus according to another aspect of the present disclosure.

As shown in FIG. 15, the display apparatus according to another aspect of the present disclosure includes third to sixth thin film transistors T3, T4, T5, and T6 and a capacitor Cst.

The third thin film transistor T3 is a driving thin film transistor, and the fourth to sixth thin film transistors T4 to T6 are switching thin film transistors. At least one of the third to sixth thin film transistors T3, T4, T5, and T6 may be formed of the above-described various thin film transistors.

The third thin film transistor T3 is switched according to the data voltage Vdata supplied from the fourth thin film transistor T4, generates a data current from the driving voltage Vdd supplied from the power line PL, and supplies it to the organic light emitting diode OLED.

The fourth thin film transistor T4 is switched according to the gate signal GS supplied to the gate line GL and supplies the data voltage Vdata supplied from the data line DL to the third thin film transistor T3.

The fifth thin film transistor T5 supplies the current of the third thin film transistor T3 to the reference line RL in response to the sensing control signal SENSE supplied from the scan line SCL. A reference voltage Vref is supplied to the reference line RL.

The sixth thin film transistor T6 is switched according to the light emission control signal EM supplied to the light emission control line EML and supplies the driving voltage Vdd supplied from the power line PL to the third thin film transistor T3.

The capacitor Cst serves to maintain the data voltage supplied to the third thin film transistor T3 for one frame, and is provided between the gate electrode and the source electrode of the third thin film transistor T3.

The organic light emitting diode OLED emits predetermined light according to a data current supplied from the third thin film transistor T3.

Accordingly, the present disclosure may have the following advantages.

According to an aspect of the present disclosure, by a second gate electrode provided apart from a first gate electrode and having a floating structure, a voltage applied to the second gate electrode may be smaller than a voltage applied to the first gate electrode. Therefore, a gate voltage applied to a portion of a first active layer overlapping with the second gate electrode may be smaller than a voltage applied to another portion of the first active layer.

According to an aspect of the present disclosure, by the second gate electrode, the gate voltage applied to a portion of the first active layer may be smaller than the gate voltage applied to another portion of the first active layer. As the gate voltage applied to the first active layer may be lowered, a thin film transistor with an improved S-factor may be implemented.

According to an aspect of the present disclosure, as the first gate electrode and the second gate structure formed of a floating structure are provided on the first active layer on the same layer, even if the gate voltage applied to the first active layer is reduced by the second gate electrode, a thin film transistor in which an on-current characteristics are not degraded by the first gate electrode may be implemented.

According to an aspect of the present disclosure, the first gate electrode and the second gate electrode may not reduce the on current characteristics while improving the S-factor of the thin film transistor.

It will be apparent to those skilled in the art that various substitutions, modifications, and variations are possible within the scope of the present disclosure without departing from the spirit and scope of the present disclosure. Therefore, the scope of the present disclosure is represented by the following claims, and all changes or modifications derived from the meaning, range and equivalent concept of the claims should be interpreted as being included in the scope of the present disclosure.

1. A thin film transistor substrate comprising:
a substrate;
an active layer disposed on the substrate;
a first gate electrode disposed on the active layer;
a second gate electrode disposed on the active layer and spaced apart from the first gate electrode;
a source electrode disposed over the active layer and connected to one side of the active layer; and
a drain electrode disposed over the active layer and connected to another side of the active layer,
wherein the second gate electrode has a floating structure.

2. The thin film transistor substrate according to claim 1,
wherein the active layer comprises a channel part, a first connection part disposed on one side of the channel part and a second connection part disposed on another side of the channel part, and
an each of the first gate electrode and the second gate electrode does not overlap with the first connection part and the second connection part.

3. The thin film transistor substrate according to claim 1,
wherein, when a voltage is applied to the first gate electrode, a voltage lower than that of the first gate electrode is applied to the second gate electrode.

4. The thin film transistor substrate according to claim 1,
wherein a direction in which the first gate electrode and the second gate electrode face each other is the same as a direction in which the source electrode and the drain electrode face each other.

5. The thin film transistor substrate according to claim 1,
wherein the first gate electrode and the second gate electrode are disposed on a same layer and do not overlap with each other, and
the first gate electrode and the second gate electrode include the same material.

6. The thin film transistor substrate according to claim 5,
wherein the active layer comprises a channel part, a first connection part disposed on one side of the channel part and a second connection part disposed on another side of the channel part, and
a portion of the channel part does not overlap with the first gate electrode and the second gate electrode.

7. The thin film transistor substrate according to claim 5,
wherein the active layer comprises a channel part, a first connection part disposed on one side of the channel part and a second connection part disposed on another side of the channel part, and
a portion of the channel part does not overlap with any one of the first gate electrode and the second gate electrode.

8. The thin film transistor substrate according to claim 1,
wherein the first gate electrode includes an extension part extending over the second gate electrode, and
the extension part of the first gate electrode overlaps with the second gate electrode.

9. The thin film transistor substrate according to claim 8, further comprising:
a second gate insulating layer disposed between the first gate electrode and the second gate electrode,
wherein the first gate electrode and the second gate electrode are disposed on different layers.

10. The thin film transistor substrate according to claim 8,
wherein the extension part of the first gate electrode is disposed on a same layer as the source electrode.

11. The thin film transistor substrate according to claim 8,
wherein the active layer includes a channel part, a first connection part disposed on one side of the channel part, and a second connection part disposed on another side of the channel part, and
an entire channel part of the active layer overlaps with the first gate electrode, and a portion of the channel part of the active layer overlaps with the second gate electrode.

12. The thin film transistor substrate according to claim 1,
wherein a direction where the first gate electrode and the second gate electrode face each other is orthogonal to a direction where the source electrode and the drain electrode face each other.

13. The thin film transistor substrate according to claim 1, further comprising:
a light shielding layer disposed under the active layer,
wherein the light shielding layer is electrically connected to the source electrode.

14. A thin film transistor substrate comprising:
a substrate;
a first thin film transistor disposed on the substrate; and
a second thin film transistor disposed on the substrate and having a structure different from that of the first thin film transistor,
wherein the first film transistor includes,
a first active layer disposed on the substrate;
a first gate electrode disposed on the first active layer;
a second gate electrode disposed on the first active layer and spaced apart from the first gate electrode;
a first source electrode disposed on the first active layer and connected to one side of the first active layer; and
a first drain electrode disposed on the first active layer and connected to another side of the first active layer,
wherein the second gate electrode has a floating structure.

15. The thin film transistor substrate according to claim 14,
wherein the second thin film transistor includes,
a second active layer disposed on the substrate;
a third gate electrode disposed on the second active layer;
a second source electrode disposed on the second active layer and connected to one side of the second active layer; and
a second drain electrode disposed on the second active layer and connected to another side of the second active layer,
wherein the second thin film transistor has a smaller number of gate electrodes than the first thin film transistor has.

16. The thin film transistor substrate according to claim 15,
wherein the first gate electrode, the second gate electrode and the third gate electrode are disposed on a same layer.

17. The thin film transistor substrate according to claim 4,
wherein the first gate electrode includes an extension part extending over the second gate electrode, and
the extension of the first gate electrode overlaps with the second gate electrode.

18. The thin film transistor substrate according to claim 14,
wherein the first gate electrode and the second gate electrode do not overlap with each other.

19. The thin film transistor substrate according to claim 14,
wherein the substrate includes a pixel region where a pixel is defined,
a plurality of driving thin film transistors and a plurality of switching thin film transistors are disposed in the pixel region,
at least one of the plurality of driving thin film transistors includes the first thin film transistor,
and at least one of the plurality of switching thin film transistors includes the second thin film transistor.

20. The thin film transistor substrate according to claim 19,
wherein the first gate electrode is electrically connected to one side of any one of the plurality of the switching thin film transistors.

21. The thin film transistor substrate according to claim 19, further comprising:
a capacitor disposed in the pixel region,
wherein the capacitor is provided by the first gate electrode of the first thin film transistor and the first source electrode of the first thin film transistor.

22. A display apparatus including a thin film transistor substrate, the thin film transistor substrate comprising:
a substrate;
an active layer disposed on the substrate;
a first gate electrode disposed on the active layer;
a second gate electrode disposed on the active layer and spaced apart from the first gate electrode;
a source electrode disposed on the active layer and connected to one side of the active layer; and
a drain electrode disposed on the active layer and connected to another side of the active layer,
wherein the second gate electrode has a floating structure.
